(19) United States
(12) Patent Application Publication
(10) Pub. No.: US 2020/0370163 A1
(43) Pub. Date: Nov. 26, 2020

(54) BARRIER FILM

(71) Applicant: NATIONAL TAIPEI UNIVERSITY OF TECHNOLOGY, Taipei City (TW)

(72) Inventors: Chung-Kuan YANG, Taipei City (TW); I-Chun Huang, Taipei City (TW); Sheng-Tung Huang, Taipei City (TW); Kun-Li Wang, Taipei City (TW)

(21) Appl. No.: 16/438,249

(22) Filed: Jun. 11, 2019

(30) Foreign Application Priority Data
May 20, 2019 (TW) 108117287

(51) Int. Cl. C23C 14/10; C23C 14/30; C23C 14/08

(52) U.S. Cl. CPC C23C 14/10; C23C 14/30; H01L 51/448; C23C 14/083; C23C 14/081

(57) ABSTRACT

A barrier film includes at least one laminate to be disposed on a substrate. The laminate includes a modifying layer proximate to the substrate and at least one multi-layered barrier unit disposed on the modifying layer. The multi-layered barrier unit includes an aluminum oxide layer, a silicon oxide layer, and a zirconium oxide layer laminated to one another.

### CROSS-REFERENCE TO RELATED APPLICATION

This application claims priority of Taiwanese Patent Application No. 108117287, filed on May 20, 2019.

### FIELD

The disclosure relates to a barrier film, and more particularly to a barrier film for preventing ingress of water vapor and oxygen into a device.

### BACKGROUND

With rapid development of flexible electronic devices such as electronic papers, dye-sensitized solar cells, organic photovoltaics, organic light-emitting diodes, and the like, a glass substrate is gradually replaced with a plastic substrate, which is thin, lightweight and flexible.

The flexible electronic devices such as the organic photovoltaics and the organic light-emitting diodes are usually provided with highly sensitive organic materials and easily oxidizable cathode metals therein. Since conventional plastic substrates have disadvantage such as relatively high oxygen and water vapor transmission rates, oxygen and water vapor contained in air can easily penetrate through the plastic substrate to reach the interior of the flexible electronic devices such that the organic materials and the cathode metals provided therein may be aged and deteriorated, resulting in reduction of stability and lifespan of the flexible electronic devices.

In order to extend the lifespan of the flexible electronic devices, a barrier film having functions of blocking water vapor and oxygen is usually applied onto the plastic substrate to improve blocking effects of the plastic substrate, so as to prevent the organic materials and the cathode metals from deteriorating and aging. In addition, a barrier film for blocking water vapor and oxygen is also required to have high light transmittance.

### SUMMARY

Therefore, an object of the disclosure is to provide a barrier film having superior oxygen blocking capability and/or enhanced water vapor blocking capability while maintaining satisfactory light transmittance.

According to the disclosure, there is provided a barrier film to be formed on a substrate. The barrier film includes at least one laminate to be disposed on the substrate. The at least one laminate includes a modifying layer and at least one multi-layered barrier unit. The modifying layer is proximate to the substrate, and is formed by solidification of a colloid solution which includes a product obtained by subjecting an alkoxysilane compound to hydrolysis and condensation to form a polymeric compound, and subjecting the polymeric compound to modification with a metal source. The at least one multi-layered barrier unit is disposed on the modifying layer, and includes an aluminum oxide layer, a silicon oxide layer, and a zirconium oxide layer laminated to one another.

### BRIEF DESCRIPTION OF THE DRAWINGS

Other features and advantages of the disclosure will become apparent in the following detailed description of the embodiment (s) with reference to the accompanying drawings, of which:

FIG. 1 is a schematic view of a first embodiment of a barrier film according to the disclosure;

FIG. 2 is a schematic view of a second embodiment of a barrier film according to the disclosure;

FIG. 3 is a schematic view of a third embodiment of a barrier film according to the disclosure;

FIG. 4 is a schematic view of a fourth embodiment of a barrier film according to the disclosure;

FIG. 5 is a schematic view of a fifth embodiment of a barrier film according to the disclosure;

FIG. 6 is a schematic view of a sixth embodiment of a barrier film according to the disclosure;

FIG. 7 is a schematic view of a seventh embodiment of a barrier film according to the disclosure;

FIG. 8 is a schematic view of an eighth embodiment of a barrier film according to the disclosure;

FIG. 9 is a schematic view of a ninth embodiment of a barrier film according to the disclosure;

FIG. 10 is a schematic view of a tenth embodiment of a barrier film according to the disclosure;

FIG. 11 depicts a graph plot of light transmittance versus wavelength curves for the barrier films of Examples 3 to 8 and Comparative Example 1;

FIG. 12 depicts color value data for the barrier films of Examples 3 to 8 and Comparative Examples 1 and 2;

FIG. 13 depicts a graph plot of light transmittance versus wavelength curves for the barrier films of Examples 9 to 12 and Comparative Example 1; and

FIG. 14 depicts color value data for the barrier films of Examples 9 to 12 and Comparative Examples 1 and 2.

### DETAILED DESCRIPTION

A barrier film according to the disclosure is adapted to be formed on a substrate, and includes at least one laminate to be disposed on the substrate. The at least one laminate includes a modifying layer and at least one multi-layered barrier unit. The modifying layer is proximate to the substrate, and is formed by solidification of a colloid solution which includes a product obtained by subjecting an alkoxysilane compound to hydrolysis and condensation to form a polymeric compound, and subjecting the polymeric compound to modification with a metal source. The at least one multi-layered barrier unit is disposed on the modifying layer, and includes an aluminum oxide layer, a silicon oxide layer, and a zirconium oxide layer laminated to one another.

A non-limiting example of the substrate is a flexible light-transmissive substrate. Examples of material for making the flexible light-transmissive substrate include, but are not limited to, polyester resin, polyacrylate resin, polyolefin resin, polycarbonate resin, polyvinyl chloride, polyimide resin, and polylactic acid. Examples of the polyester resin include, but are not limited to, polyethylene terephthalate (PET) and polyethylene naphthalate (PEN). A non-limiting example of the polyacrylate resin is polymethyl methacrylate (PMMA). Examples of the polyolefin resin include, but are not limited to, polyethylene and polypropylene. A surface of the substrate can be optionally modified by, for example, an oxygen plasma treatment, but is not limited thereto. The substrate has a thickness that is not specifically limited and that may be in a range from 25 μm to 250 μm.

As described above, the modifying layer is formed by solidification of a colloid solution which includes a product obtained by subjecting an alkoxysilane compound to hydrolysis and condensation to form a polymeric compound, and subjecting the polymeric compound to modification with a metal source. The colloid solution can be obtained by a sol-gel process. Examples of the alkoxysilane compound include, but are not limited to, propyltrimethoxysilane, 3-glycidyloxypropyltrimethoxysilane, tetraethyl orthosilicate, 3-aminopropyltriethoxysilane, 3-mercaptopropyltrimethoxysilane, and vinyltriethoxysilane. The examples of the alkoxysilane compound can be used alone or in admixture of two or more thereof. Examples of a metal source include, but are not limited to, an aluminum source, a zirconium source, and a titanium source. The examples of the metal source can be used alone or in admixture of two or more thereof. The reaction conditions for the hydrolysis and the condensation are not specifically limited, and can be suitably adjusted by the one skilled in the sol-gel process according to specific requirements for the colloid solution to be prepared. The modification with the metal source can be carried out in a physical modification manner by, for example, mixing aluminum oxide powders, zirconium oxide powders, titanium oxide powders, or combinations thereof with the polymeric compound formed by the hydrolysis and the condensation of the alkoxysilane compound, or in a chemical modification manner by subjecting an aluminum-containing chelate, a zirconium-containing chelate, a titanium-containing chelate, or combinations thereof to complexation with the polymeric compound formed by the hydrolysis and the condensation of the alkoxysilane compound. A non-limiting example of the aluminum-containing chelate is aluminum acetylacetonate (Al(acac)₃). A non-limiting example of the zirconium-containing chelate is tetrakis(2,4-pentanedionato) zirconium (IV) (Zr(acac)₄). A non-limiting example of the titanium-containing chelate is titanium diisopropoxide bis(acetylacetonate). In certain embodiments, the modifying layer has a thickness ranging from 600 nm to 1000 nm.

The aluminum oxide layer, the silicon oxide layer, and the zirconium oxide layer can be prepared from an aluminum oxide target, a silicon oxide target, and a zirconium oxide target, respectively, via evaporation. Examples of the evaporation include, but are not limited to, thermal resistance evaporation, electron beam evaporation, and laser evaporation. In certain embodiments, the evaporation is carried out by the electron beam evaporation. In certain embodiments, the evaporation is carried out in the presence of an ion source so as to enhance properties of the aluminum oxide layer, the silicon oxide layer, and the zirconium oxide layer formed by the evaporation. In certain embodiments, the aluminum oxide layer, the silicon oxide layer, and the zirconium oxide layer are prepared from the aluminum oxide target, the silicon oxide target, and the zirconium oxide target, respectively, via the electron beam evaporation in the presence of the ion source so as to obtain a barrier film having superior water vapor-blocking and oxygen-blocking capabilities. The thicknesses of the aluminum oxide layer, the silicon oxide layer, and the zirconium oxide layer are not specifically limited. In certain embodiments, the thickness of each of the aluminum oxide layer, the silicon oxide layer, and the zirconium oxide layer is in a range from 10 nm to 100 nm.

Before the disclosure is described in greater detail hereinafter, it should be noted that where considered appropriate, reference numerals or terminal portions of reference numerals have been repeated among the figures to indicate corresponding or analogous elements, which may optionally have similar characteristics.

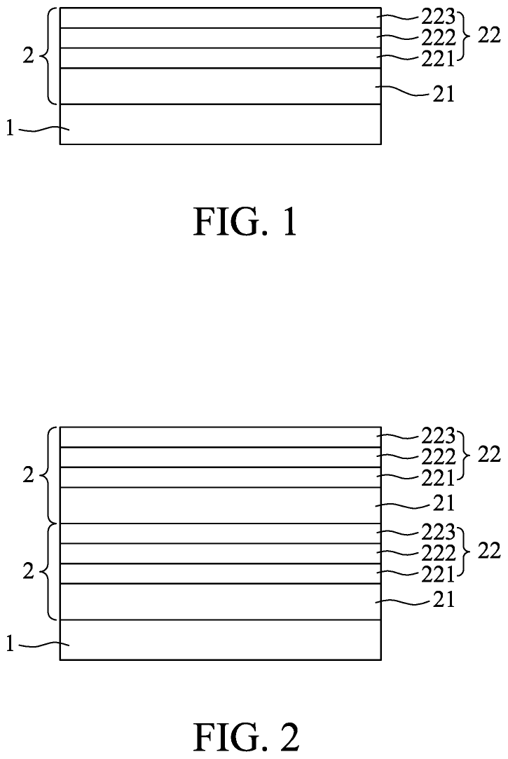

Referring to FIG. 1, a first embodiment of a barrier film according to the disclosure is formed on a substrate 1, and includes a laminate 2 disposed on the substrate 1. The laminate 2 includes a modifying layer 21 disposed on the substrate 1, and a multi-layered barrier unit 22 disposed on the modifying layer 21. The multi-layered barrier unit 22 includes an aluminum oxide layer 221, a silicon oxide layer 222, and a zirconium oxide layer 223 laminated to one another. Specifically, the aluminum oxide layer 221 is disposed on the modifying layer 21, the silicon oxide layer 222 is disposed on the aluminum oxide layer 221, and the zirconium oxide layer 223 is disposed on the silicon oxide layer 222.

In addition to the laminate configuration of the aluminum oxide layer 221, the silicon oxide layer 222, and the zirconium oxide layer 223 as illustrated in FIG. 1, it should be noted that the laminate configuration of the aluminum oxide layer 221, the silicon oxide layer 222, and the zirconium oxide layer 223 may be changed accordingly. Specifically, the aluminum oxide layer 221, the silicon oxide layer 222, and the zirconium oxide layer 223 may be laminated to one another in a direction away from the modifying layer 21 in a laminate configuration of:

(i) the aluminum oxide layer 221, the zirconium oxide layer 223, and the silicon oxide layer 222;

(ii) the silicon oxide layer 222, the aluminum oxide layer 221, and the zirconium oxide layer 223;

(iii) the silicon oxide layer 222, the zirconium oxide layer 223, and the aluminum oxide layer 221;

(iv) the zirconium oxide layer 223, the aluminum oxide layer 221, and the silicon oxide layer 222; or

(v) the zirconium oxide layer 223, the silicon oxide layer 222, and the aluminum oxide layer 221.

Referring to FIG. 2, a second embodiment of a barrier film according to the disclosure is similar to the first embodiment except that the barrier film of the second embodiment includes two laminates 2 that are laminated to each other.

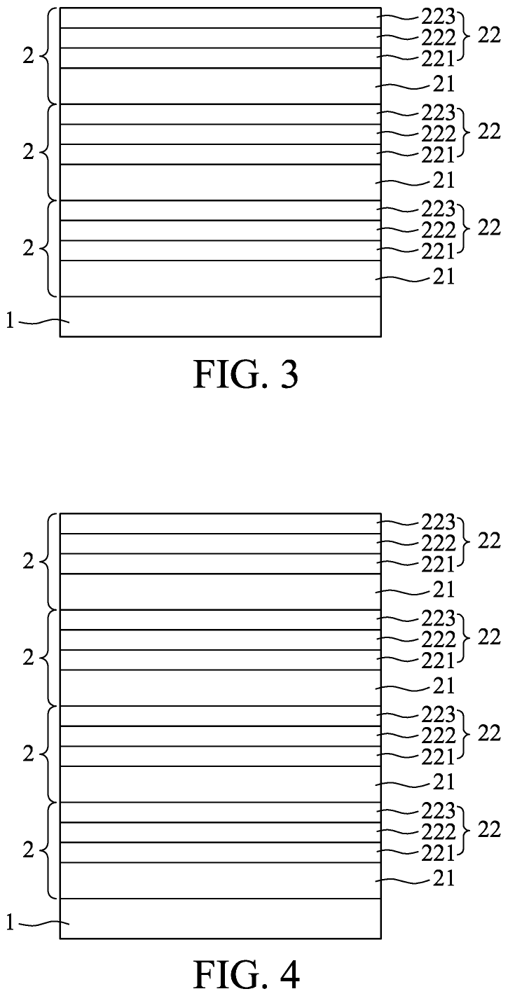

Referring to FIG. 3, a third embodiment of a barrier film according to the disclosure is similar to the first embodiment except that the barrier film of the third embodiment includes three laminates 2 that are laminated to one another.

Referring to FIG. 4, a fourth embodiment of a barrier film according to the disclosure is similar to the first embodiment except that the barrier film of the fourth embodiment includes four laminates 2 that are laminated to one another.

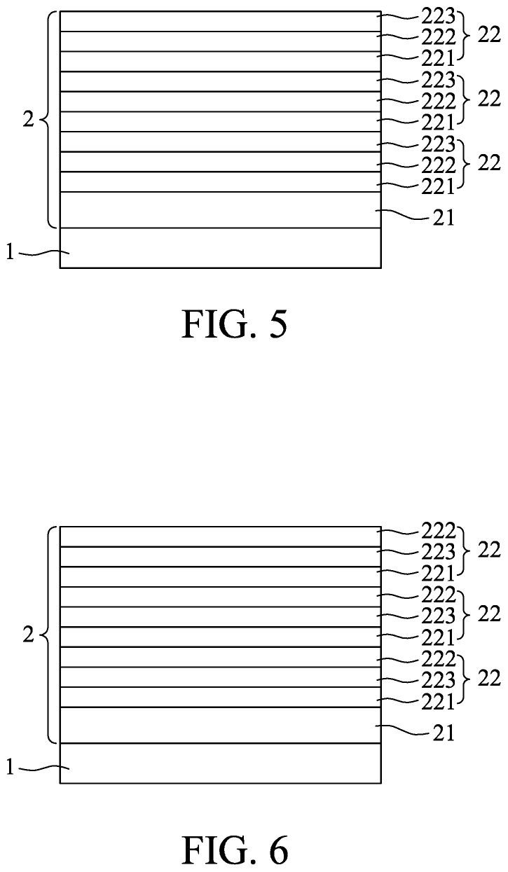

Referring to FIG. 5, a fifth embodiment of a barrier film according to the disclosure is formed on a substrate 1, and includes a laminate 2 disposed on the substrate 1. The laminate 2 includes a modifying layer 21 and three multi-layered barrier units 22 laminated to one another on the modifying layer 21. Each of the multi-layered barrier units 22 includes an aluminum oxide layer 221, a silicon oxide layer 222, and a zirconium oxide layer 223 laminated to one another. Specifically, the silicon oxide layer 222 is disposed on the aluminum oxide layer 221, and the zirconium oxide layer 223 is disposed on the silicon oxide layer 222.

Referring to FIG. 6, a sixth embodiment of a barrier film according to the disclosure is similar to the fifth embodiment except that in each of the multi-layered barrier units 22, the zirconium oxide layer 223 is disposed on the aluminum oxide layer 221, and the silicon oxide layer 222 is disposed on the zirconium oxide layer 223.

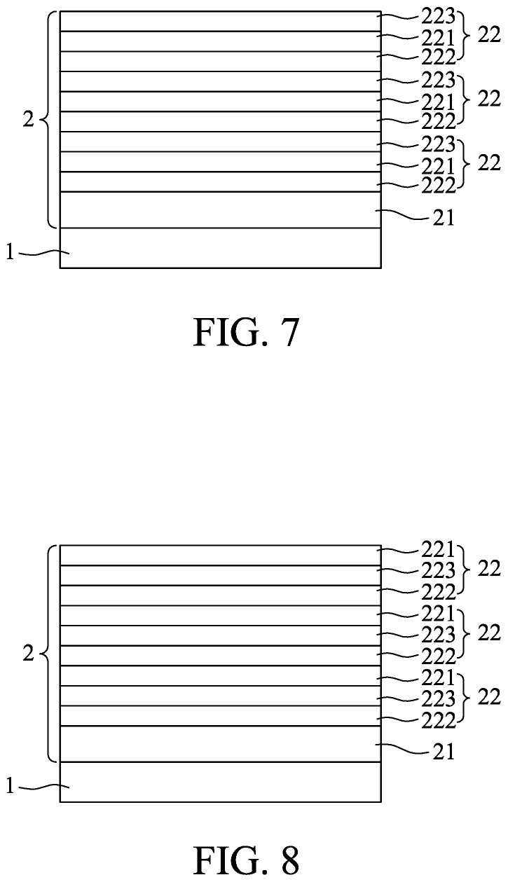

Referring to FIG. 7, a seventh embodiment of a barrier film according to the disclosure is similar to the fifth embodiment except that in each of the multi-layered barrier units 22, the aluminum oxide layer 221 is disposed on the silicon oxide layer 222, and the zirconium oxide layer 223 is disposed on the aluminum oxide layer 221.

Referring to FIG. 8, a eighth embodiment of a barrier film according to the disclosure is similar to the fifth embodiment except that in each of the multi-layered barrier units 22, the zirconium oxide layer 223 is disposed on the silicon oxide layer 222, and the aluminum oxide layer 221 is disposed on the zirconium oxide layer 223.

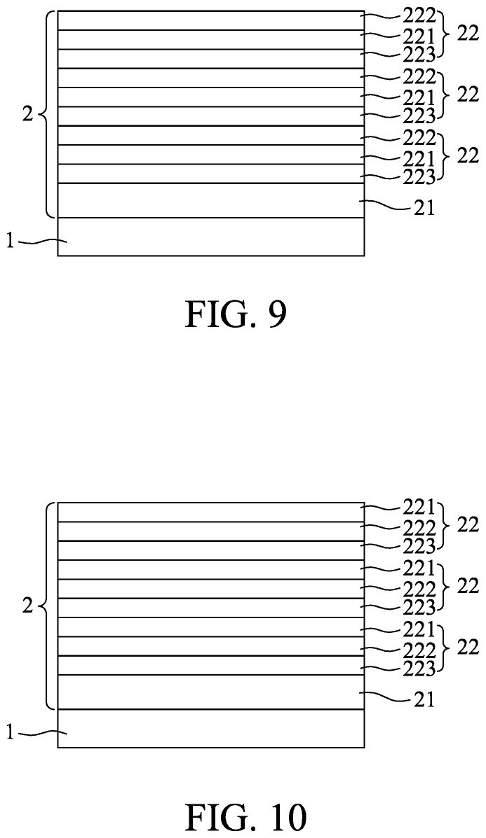

Referring to FIG. 9, a ninth embodiment of a barrier film according to the disclosure is similar to the fifth embodiment except that in each of the multi-layered barrier units 22, the aluminum oxide layer 221 is disposed on the zirconium oxide layer 223, and the silicon oxide layer 222 is disposed on the aluminum oxide layer 221.

Referring to FIG. 10, a tenth embodiment of a barrier film according to the disclosure is similar to the fifth embodiment except that in each of the multi-layered barrier units 22, the silicon oxide layer 222 is disposed on the zirconium oxide layer 223, and the aluminum oxide layer 221 is disposed on and the silicon oxide layer 222.

In the fifth to the tenth embodiments as illustrated in FIGS. 5 to 10, the laminate 2 includes three multi-layered barrier units 22. It should be noted that in certain embodiments, the laminate 2 may include two, four, or more multi-layered barrier units 22.

Examples of the disclosure will be described hereinafter. It is to be understood that these examples are exemplary and explanatory and should not be construed as a limitation to the disclosure.

### Example 1

The barrier film obtained in Example 1 has a laminate configuration shown in Table 1 below. The modifying layer, and the aluminum oxide layer, the silicon oxide layer, and the zirconium oxide layer in each of the multi-layered barrier units of the barrier film were respectively prepared according to the procedures described below.

### Preparation of the Modifying Layer:

Propyltrimethoxysilane (4 g, purchased from Sigma-Aldrich, purity: 98%), tetraethoxysilane (4 g, purchased from Sigma-Aldrich, purity: 98%), and 1-butanol (1 g, purchased from Honeywell, purity: 99.5%) were added into a round-bottom flask, followed by stirring with a magnetic stirrer to obtain a first composition. Deionized water (1.5 g), hydrochloric acid (0.03 g, concentration: 36.5%), and ethanol (0.9 g, purchased from Fisher, purity: 99.8%) were added into a sample vial, followed by stirring to obtain a second composition. The round-bottom flask containing the first composition was placed in an ice bath, and all of the second composition was added slowly to the first composition using a syringe while stirring the first composition to obtain a third composition. The round-bottom flask containing the third composition was removed from the ice bath and was stirred at room temperature (25° C.) to raise the temperature of the third composition to the room temperature. The third composition was then stirred under reflux for 1.5 hours at 80° C. to complete reaction thereof. 1-butanol (0.8 g) and aluminum acetylacetonate (0.2 g, purchased from Acros Organics, purity: 97%) were then added into the round-bottom flask, followed by adding a mixture of hydrochloric acid and 1-butanol in a ratio of 1:1 to adjust pH to 2.0, thereby obtaining a reaction mixture. The reaction mixture was stirred continuously at the room temperature (25° C.) for 2 days to obtain a colloid solution.

A polyethylene terephthalate (PET) film (Manufacturer: Nan Ya Plastics Corporation; Model: CH885Y, thickness: 125 μm) was washed by supersonic vibration in an ethanol solution (concentration: 75%) for 5 minutes and then in acetone for 5 minutes, followed by baking the PET film in an oven at 80° C. for 5 minutes, and finally cleaning a surface of the PET film with high pressure air. Thereafter, the colloid solution was coated evenly on the surface of the PET film, followed by baking the PET film coated with the colloid solution in an oven at 60° C. for 15 minutes, 80° C. for 15 minutes, and then 105° C. for 60 minutes to solidify the colloid solution so as to forma bi-layered body which includes the PET film and a modifying layer disposed on the PET film.

### Preparation of a Multi-Layered Barrier Unit:

An electron beam evaporation device (Manufacturer: Showa Shinku Co. Ltd., Japan; Model No.: SGC-22SA-IAD) having an ion beam assisted deposition function was used for the preparation of the multi-layered barrier unit. The bi-layered body was subjected to surface cleaning, and then an aluminum oxide layer, a silicon oxide layer, and a zirconium oxide layer were sequentially formed on the bi-layered body according to the procedures described below.

Surface cleaning of the bi-layered body: The bi-layered body was placed in a chamber of the electron beam evaporation device. A background pressure in the chamber was evacuated to 6×10⁻⁴ Pa, and the bi-layered body was subjected to surface cleaning for a time period of 2 minutes using an ion source under an argon flow of 15 sccm, an ion source voltage of 90 V, and an ion source current of 2.1 A.

Formation of the aluminum oxide layer: An aluminum oxide target (Manufacturer: KTX Material Co. Ltd, Taiwan, purity: 99.9%, diameter: 2 inch, thickness: 3 mm) was used. A background pressure in the chamber of the electron beam evaporation device was evacuated to 6×10⁻⁴ Pa, and electron beam evaporation was implemented for a time period from 1 minute to 5 minutes using an electron gun under an electron gun voltage of kV, an electron gun current of 200 mA, and an evaporation velocity of 4 Å/sec.

Formation of the silicon oxide layer: A silicon oxide target (Manufacturer: Ultimate Materials Technology Co. Ltd, Taiwan, purity: 99.999%) was used. Electron beam evaporation was implemented using an electron gun for a time period from 1 minute to 10 minutes under an electron gun voltage of 6 kV, an electron gun current of 40 mA, and an evaporation velocity of 2 Å/sec.

Formation of the zirconium oxide layer: A zirconium oxide target (Manufacturer: Ultimate Materials Technology Co. Ltd, Taiwan, purity: 99.99%) was used. A background pressure in the chamber of the electron beam evaporation device was evacuated to 6×10⁻⁴ Pa, and electron beam evaporation was implemented for a time period from 1 minute to 10 minutes using an electron gun under an electron gun voltage of 6 kV, an electron gun current of 165 mA, and an evaporation velocity of 2 Å/sec.

### Example 2

The barrier film of Example 2 has a laminate configuration shown in Table 1 below. The modifying layer of the barrier film of Example 2 was prepared according the same procedures as those of the modifying layer of the barrier film of Example 1. The aluminum oxide layer, the silicon oxide layer, and the zirconium oxide layer in each of the multi-layered barrier units of the barrier film of Example 2 were respectively prepared according to the procedures described below, in the presence of an ion source.

Formation of the aluminum oxide layer: An aluminum oxide target (Manufacturer: KTX Material Co. Ltd, Taiwan, purity: 99.9%, diameter: 2 inch, thickness: 3 mm) was used. A background pressure in the chamber of the electron beam evaporation device was evacuated to 6×10⁻⁴ Pa, and electron beam evaporation was implemented for a time period from 1 minute to 5 minutes using an electron gun in the presence of an ion source obtained from argon gas under an electron gun voltage of 6 kV, an electron gun current of 200 mA, an argon flow of 15 sccm, an ion source voltage of 110 V, an ion source current of 1.5 A, and an evaporation velocity of 4 Å/sec.

Formation of the silicon oxide layer: A silicon oxide target (Manufacturer: Ultimate Materials Technology Co. Ltd, Taiwan, purity: 99.999%) was used. A background pressure in the chamber of the electron beam evaporation device was evacuated to 6×10⁻⁴ Pa, and electron beam evaporation was implemented for a time period from 1 minute to 10 minutes using an electron gun in the presence of the ion source obtained from argon gas under an electron gun voltage of 6 kV, an electron gun current of 40 mA, an argon flow of 15 sccm, an ion source voltage of 110 V, an ion source current of 2.1 A, and an evaporation velocity of 2 Å/sec.

Formation of the zirconium oxide layer: A zirconium oxide target (Manufacturer: Ultimate Materials Technology Co. Ltd, Taiwan, purity: 99.99%) was used. A background pressure in the chamber of the electron beam evaporation device was evacuated to 6×10⁻⁴ Pa, and electron beam evaporation was implemented for a time period from 1 minute to 10 minutes using an electron gun in the presence of the ion source obtained from argon gas under an electron gun voltage of 6 kV, an electron gun current of 165 mA, an argon flow of 15 sccm, an ion source voltage of 110 V, an ion source current of 3.0 A, and an evaporation velocity of 2 Å/sec.

### Examples 3 to 12 and Comparative Examples 1 to 4

Each of the barrier films of Examples 3 to 12 and Comparative Examples 1 to 4 was prepared according the same procedures as those of the barrier film of Example 2, and has a laminate configuration shown in Table 1 below. In order to permit each of the barrier films of Examples 3 to 8 to have the same total thickness as that of each of the barrier films of Comparative Examples 1 and 2 for comparison, each of the barrier films of Examples 3 to 8 was further provided with a top aluminum oxide layer disposed on an uppermost one of the multi-layered barrier units. The top aluminum oxide layer was formed according to the same procedures as those of the aluminum oxide layer of each of the multi-layered barrier units.

### Property Evaluation:

### 1. Light Transmittance:

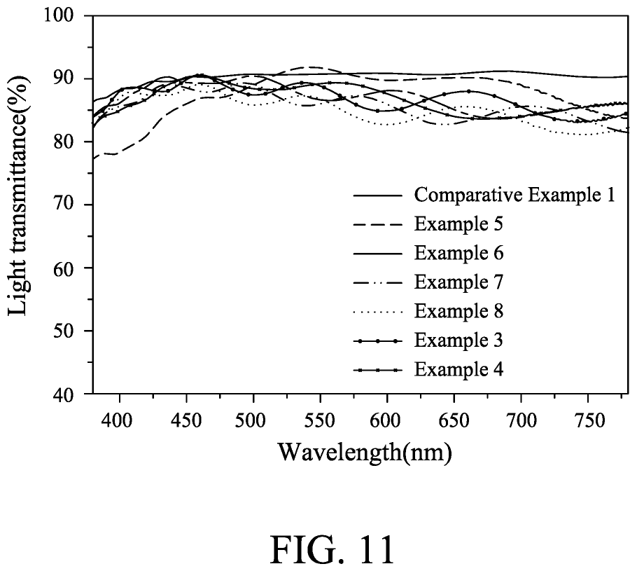

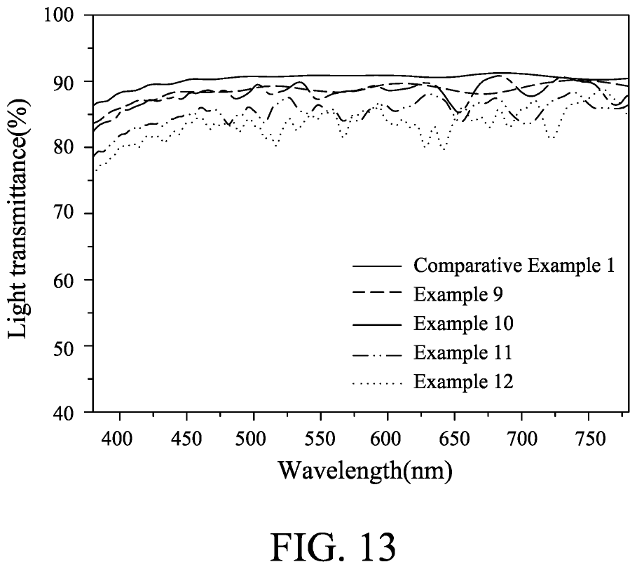

The light transmittance (T %) of each of the barrier films of Examples 1 to 12 and Comparative Examples 1 to 4 was measured using an UV-VIS spectrophotometer (Model: Agilent Cary 5000). An all-optical calibration of the UV-VIS spectrophotometer was implemented using air as a background. Thereafter, the light transmittance of each of the barrier films was measured using the UV-VIS spectrometer in a wavelength ranging from 380 nm to 780 nm. The light transmittance versus wavelength curves of the barrier films of Examples 1 to 12 and Comparative Examples 1 to 4 were shown in FIGS. 11 and 13. An average value of the light transmittance in the wavelength ranging from 380 nm to 780 nm for each of the barrier films of Examples 1 to 12 and Comparative Examples 1 to 4 was calculated. The results are shown in Table 2 below.

### 2. Color Value:

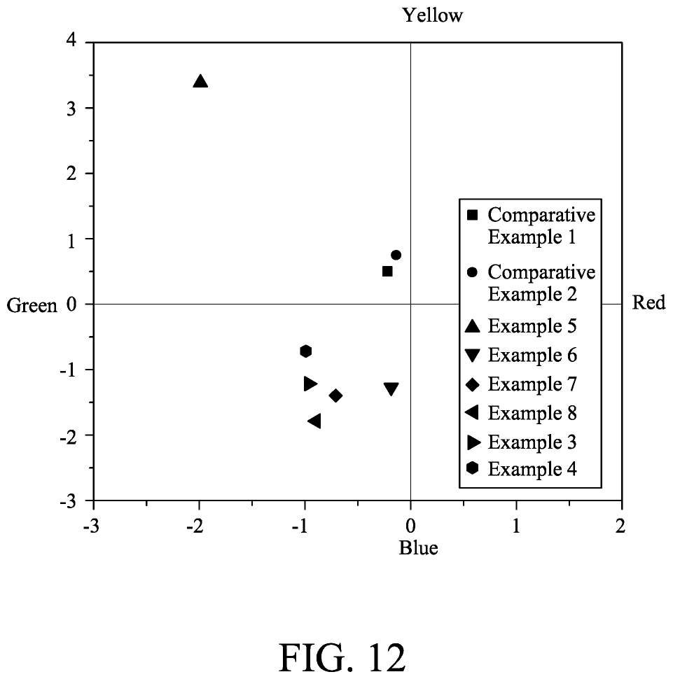

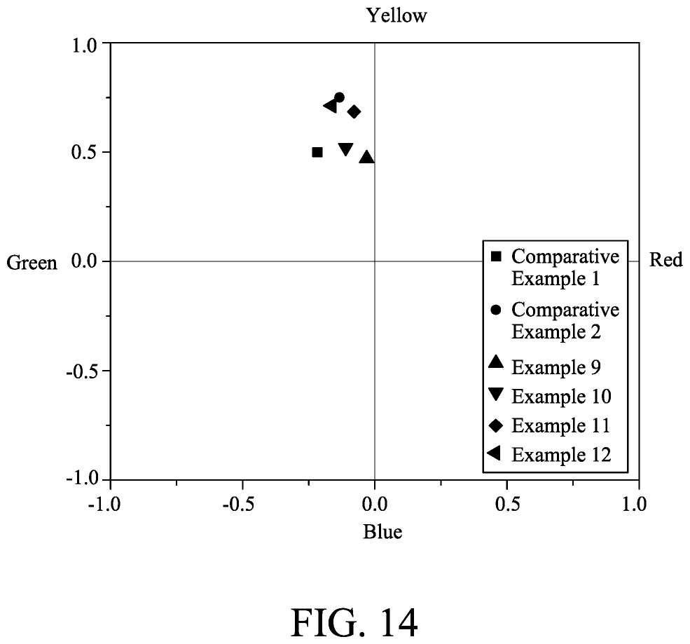

The color value in a CIELAB color space of each of the barrier films of Examples 1 to 12 and Comparative Examples 1 to 4 was measured using an UV-VIS spectrophotometer (Model: Agilent Cary 5000) together with a color grading software (Color). A positive a* value indicates redness, and a negative *a value indicates greenness. An absolute value of the a* value in a range from 0 to 1 indicates the color is not visible to the human eye. A positive b* value indicates yellowness, and a negative *b value indicates blueness. An absolute value of the b* value in a range from 0 to 1 indicates the color is not visible to the human eye. The results are shown in Table 2 below and FIGS. 12 and 14.

### 3. Water Vapor Transmission Rate (WVTR):

The water vapor transmission rate of each of the barrier films of Examples 1 to 12 and Comparative Examples 1 to 4 was measured using a water vapor permeation instrument (Manufacturer: Ametek Mocon; Model: Mocon AQUATRAN® Model 2 G, detection limit: 5×10⁻⁵ g/m²·day). The barrier film to be measured was mounted in a sample holder of the water vapor permeation instrument. The sample holder was maintained at a temperature of 37.8° C. One side of the sample holder was controlled to a relative humidity of 100% using a humidity meter equipped in the water vapor permeation instrument and was charged with nitrogen gas at a flow of 20 sccm. Water vapor carried by nitrogen gas transmitted from the one side of the sample holder through the barrier film, and entered into a P₂O₅ (phosphorous pentaoxide) sensor equipped at the other side of the sample holder to detect an amount of water vapor permeating through the barrier film, thereby analyzing the water vapor transmittance rate of the barrier film. The lower the water vapor transmission rate is, the better the water vapor-blocking capability of the barrier film is. The results are shown in Table 2 below.

### 4. Oxygen Transmission Rate (OTR):

The oxygen transmission rate of each of the barrier films of Examples 1 to 12 and Comparative Examples 1 to 4 was measured using an oxygen permeation instrument (Manufacturer: Ametek Mocon; Model: Mocon OX-TRAN Model 2/61, detection limit: 0.1 cc/m²·day). The barrier film to be measured was mounted in a sample holder of the oxygen permeation instrument. The sample holder was maintained at a temperature of 23° C. One side of the sample holder was controlled to a relative humidity of 0% and was charged with nitrogen gas at a flow of 10 sccm. Oxygen (concentration: 100%) carried by nitrogen gas transmitted from the one side of the sample holder through the barrier film, and entered into a coulombic sensor equipped at the other side of the sample holder to detect an amount of oxygen permeating through the barrier film, thereby analyzing the oxygen transmittance rate of the barrier film. The lower the oxygen transmission rate is, the better the oxygen-blocking capability of the barrier film is. The results are shown in Table 2 below.

TABLE 1

| | | | Ion beam | | Total thickness |
|---|---|---|---|---|---|
| | | | assisted | Number of | of multi-layered |
| Barrier film | | Laminate configuration of barrier film | deposition | laminate | barrier units(nm) |
| Example | 1 | P/O/Al/Si/Zr/Al/Si/Zr/Al/Si/Zr | No | 1 | 90 |
| | 2 | P/O/Al/Si/Zr/Al/Si/Zr/Al/Si/Zr | Yes | 1 | 90 |
| | 3 | P/O/Al/Si/Zr/Al/Si/Zr/Al/Si/Zr/Al* | Yes | 1 | 100 |
| | 4 | P/O/Al/Zr/Si/Al/Zr/Si/Al/Zr/Si/Al* | Yes | 1 | 100 |
| | 5 | P/O/Zr/Al/Si/Zr/Al/Si/Zr/Al/Si/Al* | Yes | 1 | 100 |
| | 6 | P/O/Zr/Si/Al/Zr/Si/Al/Zr/Si/Al/Al* | Yes | 1 | 100 |
| | 7 | P/O/Si/Al/Zr/Si/Al/Zr/Si/Al/Zr/Al* | Yes | 1 | 100 |
| | 8 | P/O/Si/Zr/Al/Si/Zr/Al/Si/Zr/Al/Al* | Yes | 1 | 100 |
| | 9 | P/O/Al/Si/Zr/ | Yes | 1 | — |
| | 10 | P/O/Al/Si/Zr/O/Al/Si/Zr | Yes | 2 | — |
| | 11 | P/O/Al/Si/Zr/O/Al/Si/Zr//O/Al/Si/Zr | Yes | 3 | — |
| | 12 | P/O/Al/Si/Zr/O/Al/Si/Zr/O/Al/Si/Zr/O/Al/Si/Zr | Yes | 4 | — |
| Comparative | 1 | P | — | — | — |
| Example | 2 | P/O | — | — | — |
| | 3 | P/O/Al/Si/Al/Si/Al/Si/Al/Si/Al/Si | Yes | 1 | 100 |
| | 4 | P/O/Al/Zr/Al/Zr/Al/Zr/Al/Zr/Al/Zr | Yes | 1 | 100 |

Note:
In Table 1,
P indicates a PET film having a thickness of 125 μm
O indicates a modifying layer having a thickness of 900 nm
Al indicates an aluminum oxide layer having a thickness of 10 nm
Si indicates a silicon oxide layer having a thickness of 10 nm
Zr indicates a zirconium oxide layer having a thickness of 10 nm
Al* indicates a top aluminum oxide layer having a thickness of 10 nm

TABLE 2

| | | Average | | | | WVTR | OTR |
|---|---|---|---|---|---|---|---|
| | | T | CIE LAB | | | (g/m² · | (cc/m² · |
| | | (%) | a* | b* | L* | day) | day) |
| Exam- | 1 | 86.23 | −0.9674 | −0.7246 | 95.1326 | 0.5380 | less than 0.1 |
| ple | | | | | | | (detection |
| | | | | | | | limit) |
| | 2 | 86.93 | −0.9376 | −0.6572 | 95.8479 | 0.0308 | less than 0.1 |
| | | | | | | | (detection |
| | | | | | | | limit) |
| | 3 | 86.82 | −0.9873 | −0.7176 | 95.3479 | 0.0334 | not |
| | | | | | | | measured |
| | 4 | 86.78 | −0.9622 | −1.2120 | 94.9364 | 0.0647 | not |
| | | | | | | | measured |
| | 5 | 87.46 | −1.9902 | 3.3923 | 96.2127 | 0.1175 | not |
| | | | | | | | measured |
| | 6 | 87.00 | −0.1862 | −1.2692 | 95.0710 | 0.1482 | not |
| | | | | | | | measured |
| | 7 | 85.78 | −0.7085 | −1.3957 | 94.5372 | 0.1535 | not |
| | | | | | | | measured |
| | 8 | 85.00 | −0.8974 | −1.7944 | 94.0891 | 0.0729 | not |
| | | | | | | | measured |
| | 9 | 88.62 | −0.0309 | 0.4697 | 95.5390 | 0.0334 | not |
| | | | | | | | measured |
| | 10 | 88.20 | −0.1109 | 0.5189 | 95.4057 | 0.0079 | not |
| | | | | | | | measured |
| | 11 | 85.27 | −0.0792 | 0.6863 | 94.1555 | 0.0011 | not |
| | | | | | | | measured |
| | 12 | 83.55 | −0.1629 | 0.7138 | 93.3593 | less | not |
| | | | | | | than | measured |
| | | | | | | 5 × | |
| | | | | | | 10⁻⁵ | |
| Com- | 1 | 90.36 | −0.2181 | 0.4984 | 96.3306 | 5.550 | not |
| parative | | | | | | | measured |
| Exam- | 2 | 90.35 | −0.1360 | 0.7460 | 96.2970 | 5.483 | not |
| ple | | | | | | | measured |
| | 3 | 89.54 | 0.3374 | 0.4075 | 96.1423 | 0.0468 | 0.3542 |
| | 4 | 86.07 | −2.9324 | 4.0440 | 96.1780 | 0.0925 | not |
| | | | | | | | measured |

As shown in Table 2, the barrier films of Examples 1 to 12 have good water vapor-blocking capability and high light transmittance. In addition, the barrier films of Examples 1 and 2 have excellent oxygen-blocking capability.

The barrier films of Examples 1 to 12 have superior water vapor-blocking capability compare to those of Comparative Examples 1 and 2. In addition, the barrier films of Examples 1 to 12 still have an average light transmittance of at least 85%, and are almost colorless.

The barrier films of Examples 2 and 3 have superior water vapor-blocking capability compared to that of Comparative Example 3. In addition, the barrier films of Examples 1 and 2 have superior oxygen-blocking capability.

The barrier film of Example 4 has superior water vapor-blocking capability compared to that of Comparative Example 4.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A barrier film adapted to be formed on a substrate, comprising:
at least one laminate adapted to be disposed on the substrate, and including:
a modifying layer proximate to the substrate, and formed by solidification of a colloid solution which includes a product obtained by subjecting an alkoxysilane compound to hydrolysis and condensation to form a polymeric compound, and subjecting said polymeric compound to modification with a metal source; and
at least one multi-layered barrier unit disposed on said modifying layer, and including an aluminum oxide layer, a silicon oxide layer, and a zirconium oxide layer laminated to one another.

2. The barrier film according to claim 1, wherein said at least one laminate includes one said multi-layered barrier unit, and said aluminum oxide layer of said multi-layered barrier unit is disposed on said modifying layer.

3. The barrier film according to claim 2, wherein silicon oxide layer of said multi-layered barrier unit is disposed on said aluminum oxide layer.

4. The barrier film according to claim 1, wherein said at least one laminate includes a plurality of said multi-layered barrier units laminated to one another.

5. The barrier film according to claim 4, wherein said aluminum oxide layer of a lowermost one of said multi-layered barrier units is disposed on said modifying layer.

6. The barrier film according to claim 5, wherein in each of said multi-layered barrier units, said silicon oxide layer is disposed on said aluminum oxide layer, and said zirconium oxide layer is disposed on said silicon oxide layer.

7. The barrier film according to claim 5, wherein in each of said multi-layered barrier units, said zirconium oxide layer is disposed on said aluminum oxide layer, and said silicon oxide layer is disposed on said zirconium oxide layer.

8. The barrier film according to claim 4, wherein said silicon oxide layer of a lowermost one of said multi-layered barrier units is disposed on said modifying layer.

9. The barrier film according to claim 8, wherein in each of said multi-layered barrier units, said zirconium oxide layer is disposed on said silicon oxide layer, and said aluminum oxide layer is disposed on said zirconium oxide layer.

10. The barrier film according to claim 8, wherein in each of said multi-layered barrier units, said aluminum oxide layer is disposed on said silicon oxide layer, and said zirconium oxide layer is disposed on said aluminum oxide layer.

11. The barrier film according to claim 1, comprising a plurality of said laminates.

12. The barrier film according to claim 1, wherein each of said aluminum oxide layer, said silicon oxide layer, and said zirconium oxide layer is respectively formed by electron beam evaporation.

13. The barrier film according to claim 12, wherein said electron beam evaporation is implemented in the presence of an ion source.
